(19) United States
(12) Patent Application Publication
(10) Pub. No.: US 2007/0207590 A1
(43) Pub. Date: Sep. 6, 2007

(54) Manufacturing method of semiconductor device

(76) Inventors: Masahiro Kiyotoshi, Sagamihara-shi (JP); Atsuko Kawasaki, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/708,059

(22) Filed: Feb. 20, 2007

(30) Foreign Application Priority Data
Feb. 20, 2006 (JP) 2006-042703

(51) Int. Cl. H01L 21/76

(52) U.S. Cl. 438/424

(57) ABSTRACT

According to an aspect of the invention, there is provided a manufacturing method of a semiconductor device including forming an isolation trench in a semiconductor substrate, filling an insulating film in the isolation trench, and annealing the filled insulating film in a vacuum or an inert gas atmosphere at a temperature that is not lower than 300° C. and less than 700° C.

### CROSS-REFERENCE TO RELATED APPLICATIONS

This application is based upon and claims the benefit of priority from prior Japanese Patent Application No. 2006-042703, filed Feb. 20, 2006, the entire contents of which are incorporated herein by reference.

### BACKGROUND OF THE INVENTION

1. Field of the Invention

The present invention relates to a manufacturing method of a semiconductor device using shallow trench isolation (STI).

2. Description of the Related Art

Downsizing of LSI has advanced with the aim of an improvement in performance of a device based on high integration (an improvement in an operating speed and realization of low power consumption) and suppression of manufacturing costs, and mass production of a device having a minimum design rule of 90 nm has already started. It is expected that design rule reduction, i.e., a minimum design rule of 65 nm, 45 nm, or 32 nm further steadily advances in the future.

On the other hand, such rapid downsizing of a device has many problems to be overcome. At a stage of developing an FEOL (front end of the line) required to form transistors, there are many problems, e.g., a reduction in film thickness of a gate insulating film, a reduction in resistance of a gate electrode, formation of an ultra shallow impurity diffused layer, and others. However, a reduction in a shallow trench isolation (STI) region is also one of serious problems.

That is because an STI width is usually greatly reduced equally with a minimum design rule, but filling a high-density plasma CVD silicon oxide film conventionally used in STI gap-fill becomes difficult in the generation of the minimum 45 nm or 32 nm process node. Anisotropic filling of an HDP (High Density Plasma enhanced)-CVD film is realized by controlling a ratio of deposition and etching. Further, this film shows excellent film quality because it is formed in plasma having a high temperature. Therefore, it has been used for STI gap-fill.

When LSI downsizing advances to approximately 45 nm, however, an upper part of the STI is rapidly closed by a deposited film overhang, and hence a sufficient STI bottom up becomes difficult. Furthermore, when downsizing of a device advances, there occurs a problem that controlling an STI shape at active area edge becomes difficult. The reason is as follows. There has been conventionally used a technology of appropriately pulling back a silicon nitride film serving as a CMP stopper formed on active area to avoid the STI at the active area edge from subsiding below a substrate surface in a final shape after gate oxide pre-treatment. However, when a width itself of the active area is scaled down to approximately 45 nm, pulling back the silicon nitride film extremely narrows a width of the silicon nitride CMP stopper on an island type active area, and hence this film does not function as the CMP stopper that is a primary role. That is the reason why it becomes difficult to employ pulling back the CMP stopper silicon nitride film.

Thus, forming a gate oxide and gate electrode in advance of STI formation becomes promising. That is, a gate insulating film and a gate electrode are formed in advance, an isolation trench for the STI is formed, and an insulating film is filled to form the STI. However, this technology has a problem of an increase in an STI gap-fill aspect ratio in comparison with the case that STI is formed in advance. At present, a silicon oxide film formed by high density plasma enhanced (HDP) CVD is utilized as standard STI gap-fill technology for STI, the gap-fill that does not generate voids (unfilled parts) is very difficult since the aspect ratio becomes 3 or above in case of STI-fill in the generation of 0.1 micron or below.

Jpn. Pat. Appln. KOKAI Publication No. 2001-267411 discloses the following technology concerning STI. According to this technology, a trench is completely filled with a first oxide film by HD-PECVD (High Density-Plasma Enhanced CVD), a second silicon oxide film is formed by a spin coat method after CMP, and a heat treatment is carried out in a dry O₂ atmosphere at 900° C. to 950° C. Based on this heat treatment, the silicon oxide films become dense, and sufficient dehydration and isolation of an R group are carried out.

Jpn. Pat. Appln. KOKAI Publication No. 2004-179614 discloses the following technology concerning an STI structure. According to this technology, polysilazane is filled in an STI trench, a polysilazane film is selectively removed by CMP, the polysilazane film is converted into an SiO₂ film by 2step BOX oxidation, and a heat treatment is carried out in an oxidizing atmosphere or an inert gas atmosphere for approximately 30 minutes at, e.g., 900° C. Based on this heat treatment, NH₃ or H₂O remaining in the SiO₂ film is eliminated to provide the dense SiO₂ film.

Jpn. Pat. Appln. KOKAI Publication No. 2005-166700 discloses the following technology concerning an STI structure. According to this technology, polysilazane is filled in an STI trench, and a heat treatment is performed in an oxidizing atmosphere, an inert gas atmosphere, or a nitrogen atmosphere at 850° C. for approximately 30 minutes to discharge NH₃ or H₂O remaining in an SiO₂ film converted from a polysilazane film, thereby making the SiO₂ film denser.

### BRIEF SUMMARY OF THE INVENTION

According to an aspect of the invention, there is provided a manufacturing method of a semiconductor device, comprising: forming an isolation trench in a semiconductor substrate; filling an insulating film in the isolation trench; and annealing the filled insulating film in a vacuum or an inert gas atmosphere at a temperature that is not lower than 300° C. and less than 700° C.

### BRIEF DESCRIPTION OF THE SEVERAL VIEWS OF THE DRAWING

FIG. 1 is a cross-sectional view showing a manufacturing step of a semiconductor device according to a first embodiment of the present invention;

FIG. 2 is a cross-sectional view showing a manufacturing step of the semiconductor device according to the first embodiment of the present invention;

FIG. 3 is a cross-sectional view showing a manufacturing step of the semiconductor device according to the first embodiment of the present invention;

FIG. 4 is a view showing water discharge characteristics according to the first embodiment of the present invention;

FIG. 5 is a cross-sectional view showing a manufacturing step of a semiconductor device according to a second and a third embodiment of the present invention;

FIG. 6 is a cross-sectional view showing a manufacturing step of the semiconductor device according to the second and the third embodiment of the present invention;

FIG. 7 is a cross-sectional view showing a manufacturing step of the semiconductor device according to the second and the third embodiment of the present invention;

FIGS. 8A and 8B are cross-sectional views showing manufacturing steps of the semiconductor device according to the second and the third embodiment of the present invention;

FIG. 9 is a view showing an AA width with respect to an RTA temperature according to the second embodiment of the present invention;

FIG. 10 is a cross-sectional view showing a manufacturing step of the semiconductor device according to the third embodiment of the present invention; and

FIG. 11 is a graph showing an amount of discharged water with respect to a TDS evaluation temperature according to the third embodiment of the present invention.

### DETAILED DESCRIPTION OF THE INVENTION

Embodiments will now be explained hereinafter with reference to the accompanying drawings.

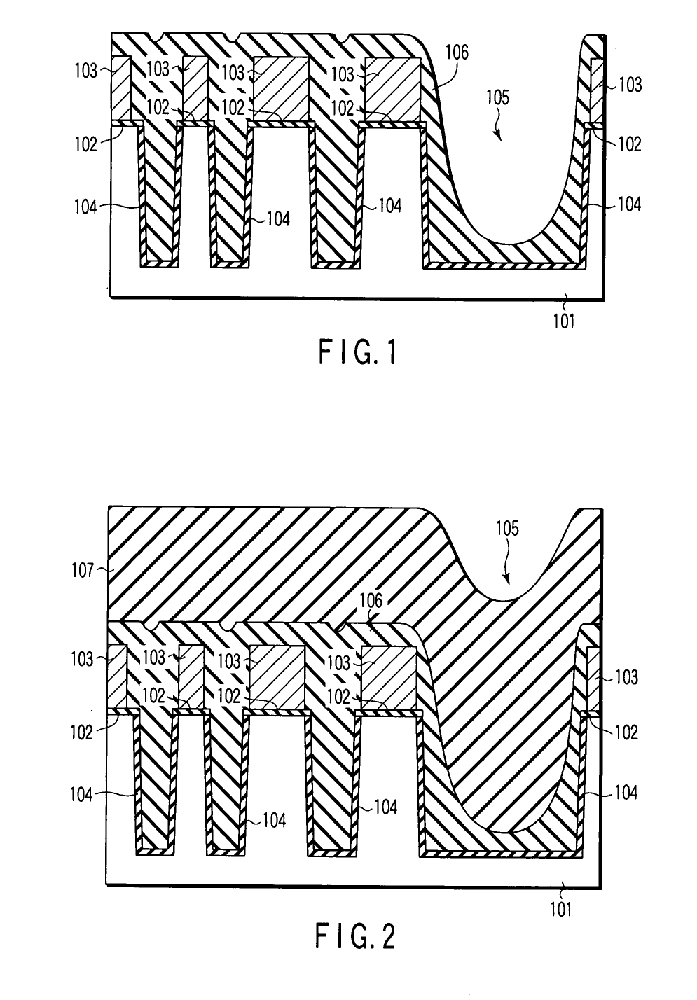

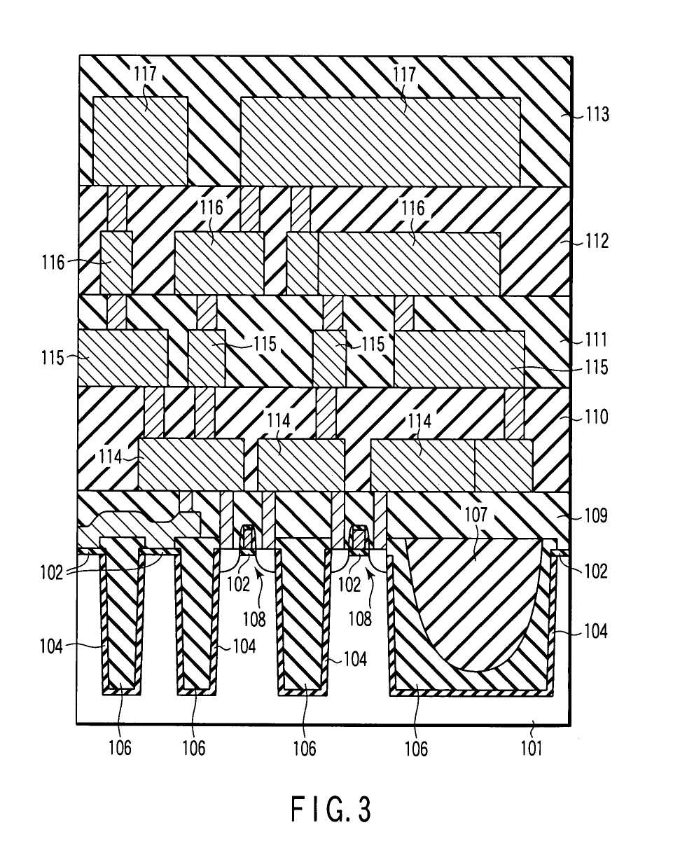

FIGS. 1 to 3 are cross-sectional views showing manufacturing steps of a semiconductor device according to a first embodiment of the present invention. This first embodiment is an example when first forming STI in a semiconductor device.

As an insulating film filling technology for STI that has been greatly downsized, it is considered that a technology of performing gap-fill by using an SOG film formed by a spin coat method or a film having flow properties, e.g., O₃/TEOS, or a technology of combining a proven HDP-CVD silicon oxide film with the flowable film to perform gap-fill is attractive. Many device manufacturers energetically examine these technologies for LSI applications.

In particular, a technology of filling a lower part of an STI trench by using a film having flowabilities and filling a conventional HDP-CVD silicon oxide film in an upper part of the STI trench is considered to be promising as a technology that does not greatly change conventional process integration in terms of STI-fill having the same film quality and the same processing-resisting properties as those of a conventional HDP-CVD silicon oxide film in the vicinity of a transistor.

However, it has been revealed that the following problem occurs when an SOG film or a flowable insulating film, e.g., an O₃/TEOS film is embedded in the STI. Such a film having flow properties contains a large amount of moisture or an OH group therein due to a film deposition process. Further, since a film density itself of such a film is low, even if the film does not contain a large amount of moisture immediately after film formation, it easily adsorbs moisture in an atmosphere in an environment, and hence it tends to contain a large amount of moisture.

Such adsorbed moisture is discharged during a high-temperature process as a post-process, e.g., a high-temperature annealing process or high-density plasma CVD, thereby causing steam oxidation. Since a diffusion speed of H₂O in a silicon oxide film is high, steam oxidation has a problem of an active area width narrowing caused by oxidation of active area, a problem of an increase in film thickness of a gate oxide film caused by occurrence of bird's beak oxidation when forming STI in a gate pre-forming structure in particular, a problem of deterioration in reliability of a device due to increase of a gate oxide thickness, and others.

According to the first embodiment, a description will be given as to a method of filling a Chemical Vapor condensation deposited film formed of SiH₄/H₂O₂ having highly flowable properties in a semiconductor substrate, then performing low-temperature annealing in a vacuum, and continuously filling a plasma CVD silicon oxide film to form STI.

First, as shown in FIG. 1, a thermally-oxidized silicon film 102 is formed with a film thickness of 5 nm on a semiconductor substrate 101, and a silicon nitride film 103 serving as a CMP polishing stopper is formed with a film thickness of 150 nm on the thermally-oxidized silicon film 102.

Then, a CVD silicon oxide film (not shown) functioning as a hard mask for reactive ion etching (RIE) is formed on an entire surface of the substrate, and a photoresist film (not shown) is coated. Subsequently, the photoresist film is patterned by a normal lithography technology. The CVD silicon oxide film is patterned by RIE with the patterned photoresist film being used as a mask, thereby forming a hard mask. Here, a minimum active area width is 45 nm. The photoresist film is removed by ashing and wet treatment with a mixture of sulfuric acid and hydrogen peroxide.

Then, the hard mask of the CVD silicon oxide film is used for sequential patterning of the silicon nitride film 103, the thermally-oxidized silicon film 102, and the semiconductor substrate 101 by RIE, thus forming a trench having an etching depth of 300 nm in the semiconductor substrate 101. Subsequently, hydrofluoric acid vapor is used to selectively remove the CVD silicon oxide film of the mask material. Thereafter, the silicon nitride film 103 is etched back approximately 5 nm in a hot phosphoric acid. Then, an inner surface of the trench is thermally oxidized to form a thermally-oxidized silicon film 104 having a film thickness of 4 nm. With the above-described steps, an isolation trench 105 for shallow trench isolation (STI) is formed.

Subsequently, a chemical vapor condensation film 106 is formed on the entire surface of the substrate. A manufacturing apparatus used in the embodiment is a cluster tool having a chemical vapor condensation chamber, an annealing chamber, and a plasma CVD chamber. The substrate can be carried between the respective chambers via using a vacuum transfer chamber without being exposed to atmospheric air.

Film deposition conditions for the chemical vapor condensation film 106 are a deposition pressure of 200 Pa and a deposition temperature of 50C. A reaction of chemical vapor condensation is as follows. When SiH₄ and H₂O₂ are introduced to the upper side of the substrate cooled to 5° C. on a temperature control plate in the CVD chamber, an intermediate having high flow properties represented by the following reaction formulas can be formed.
SiH₄+H₂O₂→SiH₃(OH)+H₂O
2SiH₃(OH)→SiH₃—O—SiH₃+H₂O
SiH₃—O—SiH₃+H₂O₂→SiH₃—O—SiH₂(OH)+H₂O
SiH₃—O—SiH₂(OH)+SiH₃ (OH)→SiH₃—O—SiH₃—O—SiH₃+H₂O

When the chemical vapor condensation film 106 is employed, the isolation trench 105 can be filled without voids (unfilled parts) as shown in FIG. 1.

As can be understood from the above-described reaction mechanism, in this reaction, H₂O is generated with dehydration and condensation, and the chemical vapor condensation film 106 is a low-density film formed at a low temperature. In consequence, a large amount of H₂O (up to lE21 cm⁻³) is adsorbed in the film. Furthermore, the OH group (a silanol group) remaining in the film also readily discharges the moisture owing to a dehydration and condensation reaction at a high temperature of 600° or above. Accordingly, when the chemical vapor condensation film 106 is annealed, steam is discharged from the film. As will be explained later, the steam discharged from the film is an oxidizing species supplied to a position near the semiconductor substrate 10, thereby causing an AA width decrease due to oxidation of the substrate.

Then, the substrate is carried into the annealing chamber having a temperature less than 300° C., and thereafter the annealing is performed on a hot plate in the annealing chamber for the purpose of dehydration and densification of the film. Annealing conditions are as follows. The annealing is executed on the hot plate set to 350° C. An annealing ambient is a vacuum, and a chamber pressure is maintained at 1 Pa or below by a turbo molecular pump. An annealing time is five minutes. It is to be noted that a sample that is not annealed and samples that are subjected to vacuum annealing for five minutes at 500° C. and 700° C. were produced as references. The vacuum annealing at 500° C. and 700° C. is executed by setting a processed substrate on the hot plate controlled to 500° C. and 700° C. Therefore, a temperature of the processed substrate is rapidly raised to an annealing temperature in approximately 10 seconds. Then, the substrate is carried to the plasma CVD chamber, and the isolation trench 105 is completely filled with a plasma CVD silicon oxide film 107 formed of SiH₄/O₂ as shown in FIG. 2. A film formation temperature of the plasma CVD is 350° C.

Subsequently, based on a CMP technology, the plasma CVD silicon oxide film 107 and the chemical vapor condensation film 106 are polished with the silicon nitride film 103 being used as a stopper so that these films 107 and 106 remain only in the isolation trench 105.

Then, the silicon nitride film 103 is removed in hot phosphoric acid, and transistors 108, inter-layer dielectric films 109, 110, 111, 112, and 113, and multilevel interconnections 114, 115, 116, and 117 are formed by a heretofore known technique.

Table 1 shows a relationship between a nominal AA width and an actual AA width with respect to each of the annealing conditions at this time.

TABLE 1
Relationship between AA width and annealing conditions

| | AA width | AA width | AA width |
|---|---|---|---|
| | (set to | (set to | (set to |
| | 45 run) | 60 nm) | 100 nm) |
| The embodiment | 44-46 nm | 58-62 nm | 96-103 nm |
| Without annealing | 38-40 nm | 52-56 nm | 90-97 nm |
| Annealing at 500° C. | 40-42 nm | 54-58 nm | 92-98 nm |
| Annealing at 700° C. | 34-36 nm | 48-52 nm | 86-93 nm |

In the annealing according to the embodiment, the nominal AA width substantially matches with the actual AA width. On the other hand, in each of the sample without any annealing and the samples subjected to the annealing at 500° C. and 700° C., the actual AA width is narrower than the nominal value, and hence it can be understood that an AA narrowing exists. That is because the silicon substrate is exposed to steam oxidation owing to moisture discharged from the chemical vapor condensation film during a high-temperature annealing or the formation of each transistor after plasma CVD film deposition. As a result, the AA width is narrowed. A degree of a reduction in AA width is relatively small at 500° C. because oxidation rate of water becomes sufficiently low at 500° C. As the temperature is increased, the AA width is more narrowed. At 700° C. or above, the AA width is further narrowed as compared with the example where any annealing is not carried out. It can be understood that the degree of a narrowing in AA width is increased due to steam oxidation when steam is rapidly discharged at a high temperature.

The following describes water discharge characteristics (temperature dependence) of the chemical vapor condensation film.

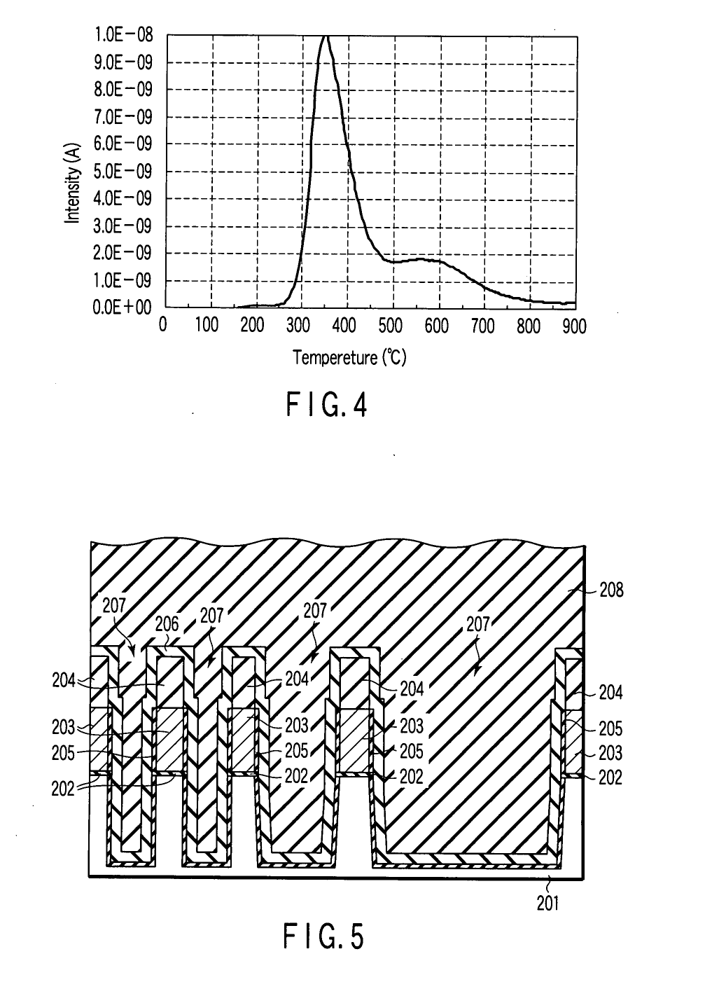

Basically, a water (H₂O) discharge peak is present near 350° C. (due to discharge of H₂O physically adsorbed in voids in the film) and near 600° C. (due to discharge of H₂O coupled with the film in a conformation of SiOH). Performing the annealing at a temperature that is not lower than 300° C. and less than 700° C. can substantially completely remove absorbed moisture. In this case, when rapid heating is carried out, the moisture in the chemical vapor condensation film is discharged at a temperature higher than an essential discharge temperature, and hence a possibility of causing, e.g., oxidation of the active are is high. As shown in FIG. 4, in case of the chemical vapor condensation film, since the moisture discharged at a temperature near 350° C. have a majority of discharged water, a heat treatment at 350° C. is adopted.

When a temperature of the thermal treatment is increased to 7000 or above, oxidation of the active area due to the moisture discharged at a higher temperature than the essential discharge temperature is apt to readily occur.

That is, when the annealing according to the embodiment is performed, the moisture in the chemical vapor condensation film can be removed without oxidation of the substrate, thereby forming the extremely narrow AA. As apparent from Table 1, such an effect becomes very remarkable when the AA width is reduced to 60 nm or below.

It is to be noted that the example using the chemical vapor condensation film as a gap-fill film has been explained in the embodiment, but the same effect can be obtained when an SOG (Spin On Glass) film is used. When the same annealing as that in the embodiment is performed in a vacuum or an inert gas atmosphere at a temperature that is not lower than 300° C. and less than 700° C., the above-explained effect can be obtained.

FIGS. 5 to 8 are cross-sectional views showing manufacturing steps of a semiconductor device according to a second embodiment of the present invention. The second embodiment is an example where a gate oxide film and a gate electrode are formed on a semiconductor substrate in advance. When the gate electrode is formed in advance, there is an advantage that concentration of, e.g., an electric field at a gate end can be suppressed, whereas occurrence of a bird's beak at a gate edge tends to become a problem in formation of STI. In the second embodiment, hybrid embedment of an HDP-CVD silicon oxide film and a perhydro-polysilazane film as one type of SOG films in a semiconductor substrate is carried out. Since the perhydro-polysilazane film adsorbs moisture in a wet etching back process, a heat treatment at a low temperature is effective in the second embodiment.

First, as shown in FIG. 5, a gate oxide film 202 is formed on a semiconductor substrate 201, a P-doped polycrystalline silicon film 203 serving as a gate electrode is formed on the gate oxide film 202, and a silicon nitride film 204 serving as a CMP polishing stopper is formed on the P-doped polycrystalline silicon film 203.

Then, a CVD silicon oxide film (not shown) functioning as a mask for reactive ion etching (RIE) is formed on an entire surface of the substrate, and a photoresist film (not shown) is applied. Subsequently, the photoresist film is patterned by a normal lithography technology, and the CVD silicon oxide film is patterned by RIE with the processed photoresist film being used as a mask, thereby forming a hard mask. Here, a minimum active area width is 55 nm. The photoresist film is removed by ashing and wet treatment with sulfuric acid hydrogen peroxide mixture.

Then, the hard mask of the CVD silicon oxide film is used to sequentially process the silicon nitride film 204, the P-doped polycrystalline silicon film 203, the gate oxide film 202, and the semiconductor substrate 201, thereby forming a trench having an etching depth of 200 nm in the semiconductor substrate 201. Subsequently, the CVD silicon oxide film of the mask material is removed by hydrofluoric acid vapor. Then, an inner surface of the trench is thermally oxidized to form a thermally-oxidized silicon film 205 having a film thickness of 4 nm.

Subsequently, a TEOS (Tetraethoxysilane) film 206 is formed with a film thickness of 15 nm on the entire surface of the substrate by an LPCVD method. Then, annealing is carried out at 800° C. for 20 minutes to provide the dense TEOS film 206. With the above-explained steps, an isolation trench 207 serving as STI is formed.

Subsequently, a polysilazane film 208 is formed on the entire surface of the substrate by a spin coat method. The polysilazane film is formed as follows.

Perhydro-silazane polymer [(SiH₂NH)n] is dispersed in xylene or dibutyl ether to generate a perhydro-silazane polymer solution, and the perhydro-silazane polymer solution is applied to the surface of the substrate by the spin coat method. Since the liquid is applied, the perhydro-silazane polymer is also filled in the isolation trench 207 having a high aspect ratio without producing voids (unfilled parts) or seams (joint-like unfilled parts).

Conditions of the spin coat method are as follows. For example, a rotating speed of the semiconductor substrate 201 is 1000 rpm, a rotating time is 30 seconds, a dropping amount of the perhydro-silazane polymer solution is 2 cc, and a target coating film thickness is 600 nm.

After applying the perhydro-silazane polymer solution, a predetermined heat treatment is performed with respect to the coating film, thereby changing the film into a perhydro-polysilazane film 208 having a low impurity concentration. First, the substrate having the coating film formed thereon is heated to 180° C. on the hot plate, and baked in an inert gas atmosphere for three minutes to volatilize a solvent in the perhydro-silazane polymer solution. On this condition, approximately several to ten-odd percent of carbon or carbon hydride due to the solvent remains as impurities in the coating film.

Then, the coating film is oxidized in a steam ambient at 280° C. to 320° C. to remove carbon or carbon hydride as an impurity in the film and also convert a large portion of Si—N bond in the film into Si—O bond. This reaction typically advances as follows.
SiH₂NH+2O→SiO₂+NH₃

The polysilazane film exposed to the heat treatment in the above-explained temperature range becomes a low-density silicon oxide film. This silicon oxide film shows a substantially uniform wet etching rate irrespective of a trench width.

Then, based on a CMP technology, the polysilazane film 208 and the TEOS film 206 are polished with the silicon nitride film 204 being used as a stopper so that the films 208 and 206 remain only in the isolation trench 207.

Subsequently, a dilute hydrofluoric acid solution having a ratio of 200:1 is used to etch back the polysilazane film 208. As already explained, at this time, the polysilazane film 208 is etched back at a substantially equal rate irrespective of an isolation trench width. However, since the polysilazane film is a film having a very low density, it absorbs moisture in the wet etching process to transform into a film containing water. As a result of estimating the amount of absorbed water by an SIMS, it has been revealed that the moisture of 1×10²¹ cm⁻³ is contained in the polysilazane film.

Then, annealing to remove the absorbed water is carried out. The annealing procedure is the following two-step processing. An annealing chamber is a batch type furnace, and the processed substrates set on a quartz board are introduced into the furnace that is set to 200° C. (the substrate can be loaded at a temperature less than 300° C. in order to avoid an influence of intrusion of oxygen in atmosphere) and subjected to nitrogen purge. Subsequently, purge is effected in a nitrogen atmosphere at 200° C. for 10 minutes to purge out convoluting oxygen that has entered the furnace. The flow rate of nitrogen is determined as a flow rate that allows complete replacement of the in-furnace atmosphere to be performed twice or more in 10 minutes. In the embodiment, since the volume of the furnace is 100 L, a flow rate of nitrogen is set to 20 SLM (the number of times of nitrogen gas replacement is 3.91 in 10 minutes). Then, the flow rate of nitrogen is maintained, the temperature in the furnace is increased to 400° C. at a heating rate of 10° C./min in 20 minutes, and this state is maintained at 400° C. for 30 minutes to carry out a first annealing (a heat treatment) step. In the heat treatment step at the above-described low temperature, moisture absorbed or adsorbed in polysilazane is discharged from the film and rapidly exhausted to the outside of the furnace.

Subsequently, the temperature of a substrate coated with the polysilazane film is increased to 800° C. at the temperature-up speed of 50° C./min sequentially in the same chamber or a vacuum in a different annealing chamber to which the substrate can be carried, and a second annealing (a heat treatment) step of performing the heat treatment for 15 minutes is carried out. Thereafter, the temperature is lowered to 200° C. at 25° C./min, and the substrate is taken out from the furnace. Based on the above-explained annealing processing, moisture in the polysilazane film 208 is removed, and the polysilazane film 208 becomes denser due to its film thickness shrinkage of approximately 12%. The thus elaborated polysilazane film 208 has been transformed into a film that demonstrates sufficient resistance with respect to, e.g., wet processing as post-processing and rarely causes moisture absorption.

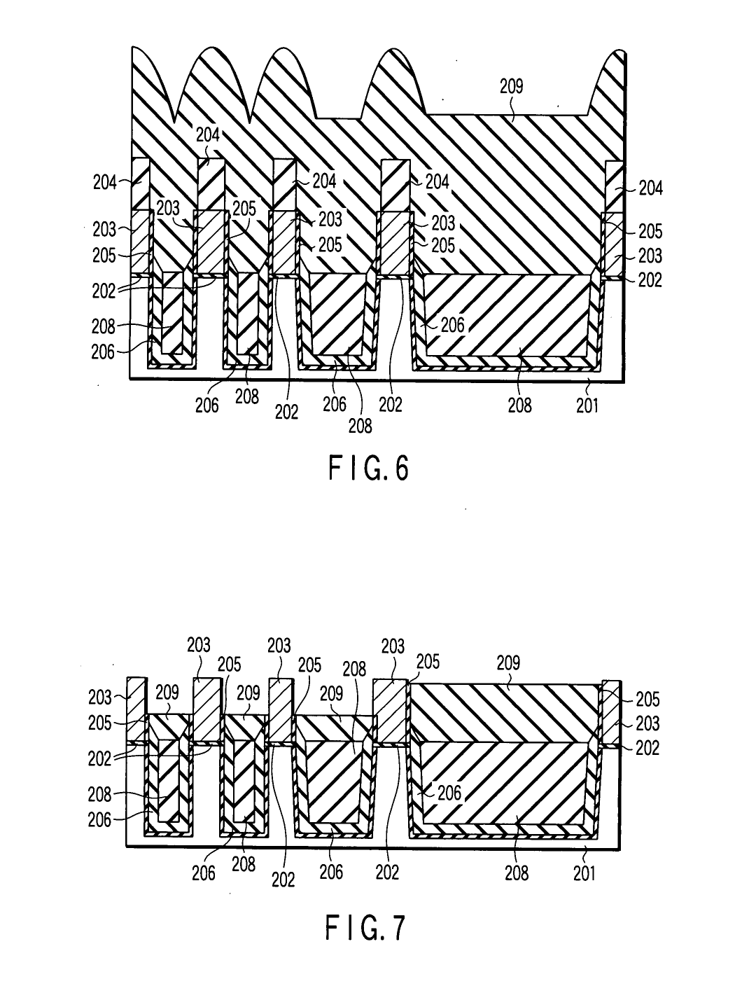

Then, as shown in FIG. 6, an HDP-CVD silicon oxide film 209 is formed on the polysilazane film 208 to completely fill spaces generated by wet etchback of the polysilazane film 208.

Further, as references, after wet etching back, the polysilazane film is annealed in nitrogen at 800° C. for 15 minutes in a conventional diffusion furnace, and then a sample having an HDP-CVD silicon oxide film deposited on the polysilazane film and a sample having an HDP-CVD silicon oxide film formed without annealing are produced. Here, the temperature at which the polysilazane film is loaded into the furnace in nitrogen annealing is 700° C., and the film formation temperature of the HDP-CVD silicon oxide film is approximately 650° C.,

Then, CMP is again performed with the silicon nitride film 204 being used as a stopper so that the HDP-CVD silicon oxide film 209 only remains in the isolation trench 207.

Subsequently, as shown in FIG. 7, the silicon nitride film 204 is etched in a hot phosphoric acid. Then, the height of the HDP-CVD silicon oxide film 209 is adjusted by a reactive ion etching technology, thereby forming an STI portion.

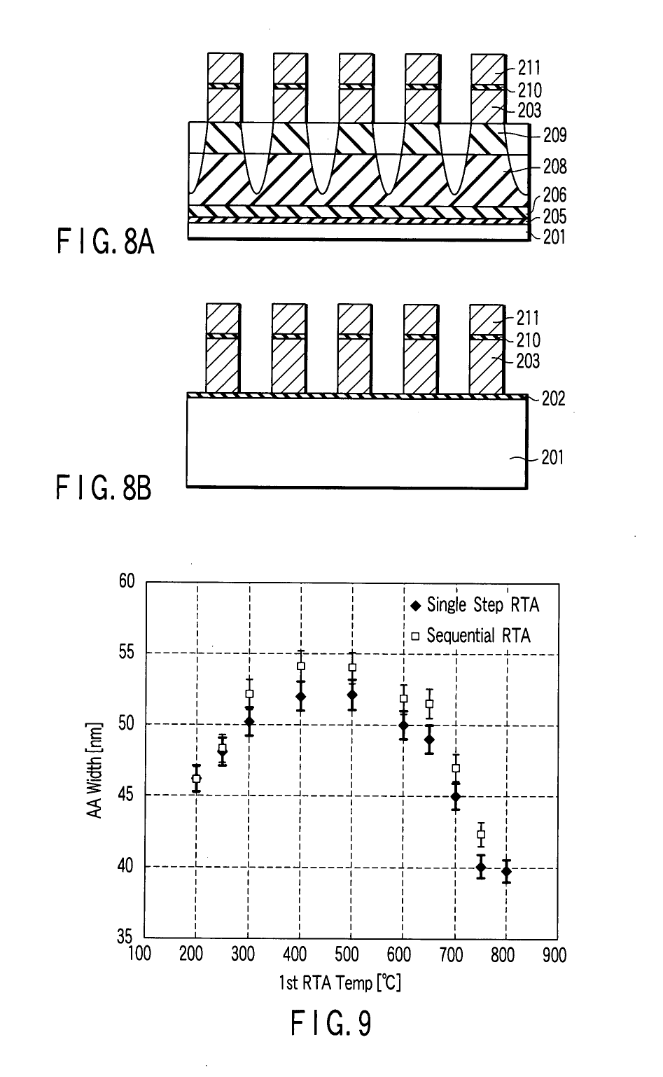

Subsequently, as shown in FIG. 8, an ONO film 210 as an inter-poly dielectric film [an IPD film] is formed by an LPCVD method, and a P-doped polycrystalline silicon film 211 serving as a control gate is formed and processed by a conventional lithography technology and reactive ion etching technology to form a gate electrode. Furthermore, interlayer dielectric films 212, 213, and 214, and multilevel interconnections 215 and 216 are formed, thus manufacturing a flash memory.

Table 2 shows an EOT (Equivalent Oxide Thickness) of the gate oxide film 202 of each sample produced in the embodiment in accordance with each AA width in a mask design.

TABLE 2
Relationship between EOT, annealing conditions, and AA width

| | | | | | | | N₂ annealing at 800° C. | | |
|---|---|---|---|---|---|---|---|---|---|
| | The embodiment | | | Without annealing | | | in diffusion furnace | | |
| Nominal AA width | 55 nm | 65 nm | 110 nm | 55 nm | 60 nm | 110 nm | 55 nm | 65 nm | 110 nm |
| Actual AA width | 55 nm | 64 nm | 111 nm | 53 nm | 57 nm | 108 nm | 52 nm | 61 nm | 106 nm |
| EOT | 8.2 nm | 8.1 nm | 8.3 nm | 8.7 nm | 8.2 nm | 8.3 nm | 9.1 nm | 8.3 nm | 8.4 nm |

As apparent from Table 2, under each of conditions, a clear difference is not observed when the AA width is 100 nm or above, but it can be understood that the EOT obtained by a method other than the embodiment is larger than that obtained by the method according to the embodiment when the AA width is 60 nm or below. As a result of examining a cross section of the gate based on a TEM at this moment, it can be comprehended that the gate oxide film becomes thicker when bird's beak oxidation progresses from both ends of the gate electrode and that the AA region itself is oxidized to narrow its width. It can be understood that the EOT is increased due to a reduction in a width W and an increase in a film thickness T since the following relationship is achieved with respect to the EOT.

$${\int }_{edge 2}^{edge 1} {ɛ}_{0} k \frac{W ( x )}{T ( x )} ⅆ x$$

This is caused by steam oxidation based on moisture discharged from the polysilazane film. Although the rate of steam oxidation exponentially increases with respect to a temperature, there is almost no oxidation rate of silicon near 400° C. Therefore, when moisture is discharged in the annealing process at a low temperature like the embodiment and then a temperature is increased in an inert gas atmosphere, steam oxidation of the silicon substrate does not occur. However, when the polysilazane film that has adsorbed moisture is directly introduced into a furnace having a high temperature and the temperature is rapidly increased, or when the temperature is instantaneously (usually approximately several seconds) by using plasma in the HDP-CVD chamber, a part of moisture discharged due to the increase in temperature oxidizes the silicon substrate.

Table 3 shows a Vₜₕ shift after repeating a Write/Erase Cycle for 10⁴ times with respect to the three conditions mentioned above.

TABLE 3
Vth shift after repeating W/E cycle for 1E4 times

| | | | Annealing |
|---|---|---|---|
| | The | Without | at 800° C. in |
| | embodiment | annealing | diffusion furnace |
| Vₜₕ shift | 1.48 V | 3.21 V | 3.48 V |
| after 1E4 W/E | | | |

It can be understood that an approximately 1.5 V Vₜₕ shift is observed in the embodiment but a fluctuation of 3 V or above occurs on the other standards. This means that data retention is difficult in an actual operation of a flash memory and nonvolatility cannot be maintained. That is, applying the embodiment can achieve both voidless embedment of the STI portion using the polysilazane film and securement of reliability of the gate oxide film.

It is to be noted that the example where the HDP-CVD silicon oxide film and the polysilazane film are used as the gap-fill films has been explained in this embodiment, but the same effect can be obtained when embedding a single polysilazane film layer. Moreover, in place of the polysilazane film, it is also possible to use any other SOG film or O₃/TEOS film, or a chemical vapor condensation film formed by using SiH₄/H₂O₂ like the first embodiment. An HTO film can substitute for the TEOS film as a liner oxide film. Additionally, the same effect can be obtained when the polysilazane film is processed in a steam ambient having a high temperature of approximately 600° C. and N in the film is removed to convert the polysilazane film into a silicon oxide film.

It is to be noted that the embodiment is not restricted to the annealing conditions mentioned above. The same effect as the above example can be obtained by setting the processed substrate into the annealing chamber and replacing the atmosphere at a temperature less than 300° C., carrying out the first annealing step in a vacuum or an inert gas atmosphere at a temperature that is not lower than 300° C. and less than 700°, and continuously effecting the second annealing step in a vacuum or an inert gas atmosphere at a temperature that is not lower than 700° C.

The following experiment was conducted to further clarify an application range of the effect of the embodiment.

A sample having the same structure as that of the sample used to evaluate the electrical characteristics was evaluated, and such a heat treatment as shown in the following Table 4 was performed by using an RTP (rapid thermal processor). After end of the heat treatment, the filled films in the STI were completely removed by hydrofluoric-acid-based wet etching, and then an AA width was measured by using a dimension SEM. However, when performing RTA twice, the RTA processing was sequentially performed to avoid adsorption of moisture between the two RTA processing steps. Each RTA processing time is five minutes.

TABLE 4

| 1st RTA Temp [° C.] | 2nd RTA Temp [° C.] |
|---|---|
| 200 | — |
| 250 | — |
| 300 | — |
| 400 | — |
| 500 | — |
| 600 | — |
| 650 | — |
| 700 | — |
| 750 | — |
| 800 | — |
| 200 | 800 |
| 250 | 800 |
| 300 | 800 |
| 400 | 800 |
| 500 | 800 |
| 600 | 800 |
| 650 | 800 |
| 700 | 800 |
| 750 | 800 |

FIG. 9 shows its result.

In FIG. 9, the AA width is plotted with respect to a 1st RTA temperature depicted in Table 4. This figure shows that an influence of oxidation due to discharged moisture has less impact as the AA width is increased. It is to be noted that the RTA has a higher heating rate than that of the diffusion furnace. When an RTA temperature of Single Step or a 1st RTA temperature of Sequential annealing is not lower than 700° C., oxidation due to discharge of H₂O is apt to occur as compared with an example where annealing processing is performed in the diffusion furnace at the same temperature.

The following tendencies can be understood from FIG. 9.

(1) In case of Single Step, a narrowing of the AA width can be observed when the RTA temperature is not higher than 300° C. It can be considered that this reduction is caused by oxidation due to discharge of H₂O during the HDP-CVD process.

(2) In case of Single Step, a tendency that the AA width is reduced together with the RTA temperature when the RTA temperature is not lower than 500° C. is observed. In particular, when the RTA temperature is not lower than 700° C., the AA width is greatly narrowed. It is considered that this narrowing is caused by oxidation due to water discharged from polysilazane in the RTA process and the HDP-CVD process.

(3) In case of Sequential (RTA is performed twice at different temperatures), a reduction in the AA width is improved under all conditions as compared with Single Step. It is considered that this improvement is achieved because oxidation due to water discharged from polysilazane during the HDP-CVD process is suppressed as a result of complete discharge of H₂O at the 2nd RTA at 800° C.

It can be understood from the above-mentioned experimental result that the thermal treatment at a temperature that is not lower than 300° C. and less than 700° C. or, preferably, a temperature that is not greater than 650° C. is effective for suppression of oxidation due to discharged water and that adding the heat treatment at a temperature of 700° C. or above that is higher than that in the first heat treatment or, preferably, the heat treatment at a temperature that is not lower than 800° C. can enhance the effect of suppressing oxidation due to discharged water in a post-process.

FIGS. 5 to 8 and FIG. 10 are cross-sectional views showing manufacturing steps of a semiconductor device according to a third embodiment of the present invention. The third embodiment is also an example where a gate oxide film and a gate electrode are formed on a semiconductor substrate in advance. Although the third embodiment is basically the same as the second embodiment, a heat treatment at a low temperature is performed to remove moisture adsorbed in a perhydro-polysilazane film that is damaged during the gate electrode patterning.

Like the second embodiment, first, as shown in FIG. 5, a gate oxide film 202 is formed on a semiconductor substrate 201, a P-doped polycrystalline silicon film 203 serving as a gate electrode is formed on the gate oxide film 202, and a silicon nitride film 204 functioning as a CMP polishing stopper is formed on the P-doped polycrystalline silicon film 203.

Then, a CVD silicon oxide film (not shown) serving as a mask of reactive ion etching (RIE) is formed on an entire surface of the substrate, and a photoresist film (not shown) is coated. Subsequently, the photoresist film is patterned by a conventional lithography technology, and the silicon oxide film is patterned by RIE with the patterned photoresist film being used as a mask, thereby forming a hard mask. Here, a minimum, active area width is 55 nm. The photoresist film is removed by ashing and wet treatment with a sulfuric acid hydrogen peroxide solution mixture.

Subsequently, the hard mask of the CVD silicon oxide film is used for sequential patterning of the silicon nitride film 204, the P-doped polycrystalline silicon film 203, the gate oxide film 202, and the semiconductor substrate 201 by RIE, thus forming a trench having an etching depth of 200 nm in the semiconductor substrate 201. Then, the CVD silicon oxide film of the mask material is removed by hydrofluoric acid vapor. Subsequently, an inner surface of the trench is thermally oxidized to form a thermally-oxidized silicon film 205 having a film thickness of 4 nm.

Then, a TEOS film 206 is formed with a film thickness of 15 nm on the entire surface of the substrate by an LPCVD method. Subsequently, annealing is performed at 800° C. for 20 minutes to make the TEOS film 206 denser. With the above-explained processing, an isolation trench 207 serving as STI is formed. Subsequently, a polysilazane film 208 is formed on the entire surface of the substrate by a spin coat method.

Then, the polysilazane film 208 and the TEOS film 206 are polished by a CMP technology with the silicon nitride film 204 being used as a stopper so that the films 208 and 207 remain in the isolation trench 207 alone.

Subsequently, the polysilazane film 208 is etched back by using a dilute hydrofluoric acid solution having a ratio of 200:1, and annealing to remove adsorbed water is performed like the second embodiment. H₂O in the polysilazane film 208 is removed, and the polysilazane film 208 becomes dense due to its film thickness shrinkage of approximately 12%. The thus densified polysilazane film 208 has been converted into a film that demonstrates sufficient process endurance with respect to, e.g., wet etching and rarely adsorbs moisture.

Then, as shown in FIG. 6, an HDP-CVD silicon oxide film 209 is formed on the polysilazane film 208 to completely fill spaces produced when the polysilazane film 208 is etched back.

Subsequently, CMP is again carried out with the silicon nitride film 204 being used as a stopper so that the HDP-CVD silicon oxide film 209 only remains in the isolation trench 207.

Then, as shown in FIG. 7, the silicon nitride film 204 is removed in a hot phosphoric acid. Subsequently, a height of the HDP-CVD silicon oxide film 209 is adjusted by the reactive ion etching technology, thereby forming an STI portion.

Then, as shown in FIGS. 8A and 8B, an ONO film 210 as an inter-poly dielectric film [an IPD film] is formed by the LPCVD method to form a P-doped polycrystalline silicon film 211 serving as a control gate, and the film is patterned by a conventional lithography technology and reactive ion etching technology to form a gate electrode. It is to be noted that FIG. 8A is a cross-sectional view of the STI portion, and FIG. 8B is a cross-sectional view of an AA portion.

However, the STI portion is largely recessed by overetching when processing the gate electrode, the HDP-CVD silicon oxide film 209 is removed, and a surface of the polysilazane film 208 is damaged due to reactive ion etching exposure. After etching, in order to remove a deposit, ashing and etching using a dilute hydrofluoric acid solution are carried out. In the process, since an upper part of the polysilazane film 208 having a processing damage is apt to adsorb moisture, a heat treatment is effective in nitrogen at 500° C. (or not lower than 500° C. and not higher than 650° C.) for 10 minutes in this state.

The purpose of the heat treatment will now be explained with reference to FIG. 11. In FIG. 11, each temperature, i.e., 250° C., 400° C., or 500° C. is maintained constant for 10 minutes to evaluate a TDS (Thermal Desorption Spectroscopy). It can be understood from FIG. 11 that discharged moisture due to adsorbed water is eliminated at a temperature equal to or below 500° C., and that H₂O is completely discharged at each H₂O discharge peak within 10 minutes even though the plurality of H₂O discharge peaks are present (a right-hand side of a peak of the TDS is vertical because H₂O is completely discharged while keeping the sample at the same temperature). As shown in FIG. 11, almost all of moisture adsorbed in polysilazane can be removed at 500° C., and hence adsorbed moisture involved by the gate electrode patterning can be removed at a low temperature with which bird's beak oxidation is not caused during the thermal treatment. It is to be noted that a water discharge peak at 500° C. or above exists at a temperature of approximately 650° C. When a rapid thermal processing is carried out at a temperature higher than this value, e.g., 700° C., bird's beak oxidation involved by rapid discharge of water is disadvantageously apt to occur.

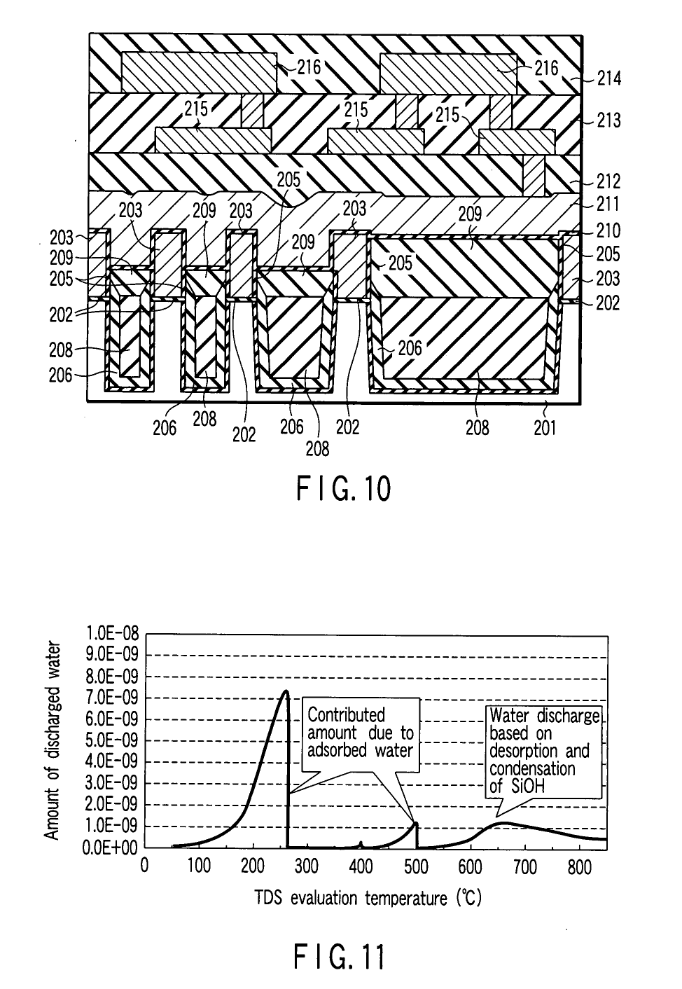

Further, as shown in FIG. 10, interlayer dielectric films 212, 213, and 214, and multilevel interconnections 215 and 216 are formed, thereby manufacturing a flash memory.

Table 5 shows an EOT (Equivalent Oxide Thickness) of the gate oxide film 202 in a sample manufactured in the embodiment in accordance with each AA width in a mask design.

TABLE 5
Relationship between EOT, annealing conditions, and AA width

| | Third embodiment | | | Without annealing | | | Second embodiment | | |
|---|---|---|---|---|---|---|---|---|---|
| Nominal AA width | 55 nm | 65 nm | 110 nm | 55 nm | 60 nm | 110 nm | 55 nm | 65 nm | 110 nm |
| Actual AA width | 56 nm | 64 nm | 110 nm | 53 nm | 57 nm | 108 nm | 55 nm | 64 nm | 111 nm |
| EOT | 8.2 nm | 8.1 nm | 8.2 nm | 8.7 nm | 8.2 nm | 8.3 nm | 8.2 nm | 8.1 nm | 8.3 nm |

It can be understood from Table 5 that characteristics equivalent to those of the second embodiment can be obtained.

Table 6 shows a Vₜₕ shift after repeating a Write/Erase Cycle for 10⁴ times with respect to the three conditions mentioned above.

TABLE 6
Vₜₕ shift after repeating W/E cycle for 1E4 times

| | Third | Without | Second |
|---|---|---|---|
| | embodiment | annealing | embodiment |
| Vₜₕ shift | 1.25 V | 3.21 V | 1.48 V |
| after 1E4 W/E | | | |

In the third embodiment, a approximately 1.5 V Vₜₕ shift in the second embodiment is further suppressed by 0.23 V. It is considered that the Vₜₕ shift is improved because deterioration in a tunnel oxide film due to steam oxidation is alleviated. That is, applying the third embodiment can achieve both voidless gap-fill in the narrow STI portion using the polysilazane film and securement of reliability of the gate oxide film, and it can be comprehended that reliability can be further improved.

It is to be noted that the example using the HDP-CVD silicon oxide film and the polysilazane film as the gap-fill films has been explained in this embodiment, but the same effect can be obtained in case of filling the single polysilazane film. Furthermore, in place of the polysilazane film, any other SOG film or O₃/TEOS film or a chemical vapor condensation film formed by using SiH₄/H₂O₂ like the first embodiment can be utilized. As a liner oxide film, an HTO film can be used in place of the TEOS film. Moreover, when the polysilazane film is processed in a water vapor atmosphere at a high temperature of approximately 600° C. to remove N in the film so that the polysilazane film is converted into a silicon oxide film, the same effect can be obtained.

As explained above, the embodiment of the present invention provides a manufacturing method of a semiconductor device. According to this manufacturing method, as a part or all of a filled insulating film for shallow trench isolation (STI) of the semiconductor device, an SOG film, an O₃/TEOS film, or a chemical vapor condensation film, e.g., an SiH₄/H₂O₂ film is filled. The filled insulating film is planarized by the CMP technology, and etching back is carried out to adjust a height of the film. Thereafter, a thermal treatment is carried out in an inert gas atmosphere or a vacuum at a temperature that is not lower than 300° C. and less than 700° C. As a result, desorption of moisture adsorbed in the film is promoted, and an active area width increase or deterioration in device characteristics at a subsequent high-temperature process, e.g., an annealing process or a high-density plasma CVD process is suppressed.

That is, moisture can be discharged from the filled insulting film without causing steam oxidation due to discharge of moisture absorbed or adsorbed in the filled insulating film. Therefore, a problem of occurrence of an AA width narrowing due to water vapor oxidation can be suppressed. Additionally, although the filled insulating film of the STI requires high-temperature densification annealing, the number of steps is not increased when the sequence according to the embodiment is used. Further, after annealing for dehydration, continuously performing high-temperature annealing can suppress water re-adsorption after the annealing.

Furthermore, the SOG film or the chemical vapor condensation film used as the gap-fill insulating film has flow properties and can be filled in a narrow isolation trench, thereby downsizing the STI. The gate electrode pre-forming structure is advantageous in downsizing of the device since an STI edge is not etched by the hydrofluoric-acid-based wet etching as pre-treatment for the gate oxide film formation. On the contrary, since the gate electrode is formed in advance, the structure is weak against bird's beak oxidation due to the gap-fill insulating film of the STI. However, the utilization of the annealing of the embodiment for the structure enables the acquisition of excellent device characteristics even if the device downsizing is performed.

As explained above, according to the embodiment, it is possible to overcome problems, e.g., a narrowing of the active area width that occurs when the filled insulating film having flow properties in the STI is used or deterioration in reliability of a device having a gate pre-forming structure. Therefore, the very narrow STI can be formed while suppressing an influence on device characteristics, thus improving performance based on further downsizing of a semiconductor device.

According to the embodiment, it is possible to provide the manufacturing method of a semiconductor device intended to improve performance involved by downsizing of the semiconductor device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A manufacturing method of a semiconductor device, comprising:
forming an isolation trench in a semiconductor substrate;
filling an insulating film in the isolation trench; and
annealing the filled insulating film in a vacuum or an inert gas atmosphere at a temperature that is not lower than 300° C. and less than 700° C.

2. The manufacturing method of a semiconductor device according to claim 1,
wherein, after the annealing, the filled insulating film is sequentially annealed in a vacuum or an inert gas atmosphere at a temperature that is not lower than 700° C.

3. The manufacturing method of a semiconductor device according to claim 1,
wherein the annealing includes:
a process of heating the atmosphere to a predetermined temperature that is not lower than 300° C. and less than 700° C. after introduction of the semiconductor substrate into an annealing chamber subjected to vacuum purge or insert gas purge at a temperature that is less than 300° C., and performing the annealing at the predetermined temperature for a predetermined time.

4. The manufacturing method of a semiconductor device according to claim 1,
wherein the filled insulating film is an SOG film or a chemical vapor condensation film that includes moisture or adsorbs moisture.

5. The manufacturing method of a semiconductor device according to claim 4,
wherein the filled insulating film is a chemical vapor condensation film that is formed by using SiH₄ and H₂O₂.

6. The manufacturing method of a semiconductor device according to claim 1,
wherein the filled insulating film is an O₃/TEOS film.

7. The manufacturing method of a semiconductor device according to claim 1,
wherein the filled insulating film includes an SOG film and a chemical vapor condensation film that include moisture or adsorb moisture.

8. The manufacturing method of a semiconductor device according to claim 1,
wherein a gate insulating film and a gate electrode are formed on the semiconductor substrate in advance.

9. The manufacturing method of a semiconductor device according to claim 1,
wherein the filled insulating film includes a polysilazane film.

10. The manufacturing method of a semiconductor device according to claim 9,
Wherein the polysilazane film is heated at a temperature that is not lower than 500° C. and not higher than 650° C.

11. The manufacturing method of a semiconductor device according to claim 1,
wherein the filled insulating film includes a high-density plasma CVD film and an SOG film.

12. The manufacturing method of a semiconductor device according to claim 11,
wherein the high-density plasma CVD film is a silicon oxide film.

13. The manufacturing method of a semiconductor device according to claim 11,
wherein the SOG film is a polysilazane film.
